(19) United States
(12) Patent Application Publication
(10) Pub. No.: US 2006/0255385 A1
(43) Pub. Date: Nov. 16, 2006

(54) Memory device of the one-time-programmable type, and programming method for same

(75) Inventor: Jean-Pierre Schoellkopf, Grenoble (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/401,101

(22) Filed: Apr. 10, 2006

(30) Foreign Application Priority Data
Apr. 11, 2005 (FR) 0503571

(51) Int. Cl. H01L 29/94

(52) U.S. Cl. 257/296

(57) ABSTRACT

A memory cell includes a bipolar transistor buried in a first part of the substrate and a dielectric region formed from a dielectric material capable of being subject to irreversible breakdown in the presence of a breakdown voltage difference applied thereto. This dielectric region is disposed on top of the substrate and has a first surface in electrical contact with a first electrode of the transistor, and a second surface opposite to the first. A programming circuit applies a breakdown voltage difference between the second surface of the dielectric region and the control electrode of the transistor so as to make the p-n junction of the transistor, formed between the first electrode and the control electrode, conduct.

### PRIORITY CLAIM

The present application claims priority from French Application for Patent No. 05 03571 filed Apr. 11, 2005, the disclosure of which is hereby incorporated by reference.

### BACKGROUND OF THE INVENTION

1. Technical Field of the Invention

The present invention relates to integrated circuits, and notably integrated memory devices of the “one-time-programmable” type, also known by those skilled in the art as OTP memory.

2. Description of Related Art

The OTP memory is well known to those skilled in the art. It comprises fusible elements, such as capacitors, that are made to break down electrically, in other words the dielectric of the capacitor is damaged in an irreversible manner, such that the latter then behaves like a resistor of low value. Such memories conventionally comprise access transistors of the field-effect type, and the fabrication of such memories requires special precautions so as not to damage the access transistors during the irreversible programming of the memory cells of the memory.

There is a need in the art to provide a solution to the problem of access transistor damage and embodiments of the present invention propose a totally different architecture of irreversibly electrically programmable or one-time-programmable memories, which does not involve the use of field-effect transistors in the memory matrix or memory array.

There is also a need in the art to provide a memory cell or dot with a very high area density, for example of the order of 0.25 μm² per bit, in a 65 nm CMOS technology, as compared with 100 μm² per bit currently.

There is still further a need in the art to provide a memory architecture that offers a low programming voltage and high read speed.

### SUMMARY OF THE INVENTION

According to a first aspect of the invention, an integrated circuit is thus provided comprising a memory device of the irreversibly electrically programmable type and comprising at least one memory cell.

According to a general characteristic of this aspect of the invention, the memory device is formed within and on a first part of a semiconductor substrate and the memory cell comprises a bipolar transistor buried in the first part of the substrate, together with a dielectric region formed from a dielectric material capable of being subject to irreversible breakdown in the presence of a breakdown voltage difference that is applied to it. This dielectric region is disposed on top of the substrate and has a first surface, for example its lower surface, in electrical contact with a first electrode of the transistor, and a second surface opposite to the first, for example its upper surface. The memory device furthermore comprises programming means capable of applying the breakdown voltage difference between the second surface of the dielectric region and the control electrode of the transistor so as to make the p-n junction of the transistor, formed between the first electrode and the control electrode, conduct.

According to one embodiment of the invention, the dielectric region is situated on top of an insulating layer covering the first part of the substrate and the memory cell comprises a metal interconnect (commonly called “contact” by those skilled in the art) passing through the insulating layer between the first surface of the dielectric region and the first electrode of the bipolar transistor.

The integrated circuit also advantageously comprises at least one active component, for example a CMOS component, and for example, more generally, a CMOS core formed within and on a second part of the same substrate, this second part also being covered by the insulating layer.

In other words, the invention is noteworthy in the sense that it allows the fabrication of OTP memories, referred to as “embedded” memories according to a terminology usually employed by those skilled in the art, in other words memories that are for example fabricated in conjunction with other components by the same technological process, and that are to be integrated together within the same substrate of, for example, an application specific integrated circuit (ASIC).

According to one embodiment of the invention, the bipolar transistor of the memory cell is formed from a multilayer of three semiconductor regions situated within the first part of the substrate, in other words that part within which the OTP memory is fabricated. The metal interconnect (contact) passes through the insulating layer between the first surface of the dielectric region and the upper semiconductor region of the multilayer. The cell programming means comprise a first electrically conducting connection means in contact with the middle semiconductor region of the multilayer and a second electrically conducting means in contact with the second surface, for example the upper surface, of the dielectric region.

According to one variant of the invention in which the memory device comprises a matrix of memory cells, a continuous dielectric layer, formed from the dielectric material capable of being subject to electrical breakdown, is provided. This continuous dielectric layer extends over the bipolar transistors of all the cells and incorporates the dielectric regions of the cells.

More precisely and according to one embodiment of this variant, the continuous dielectric layer, formed from the dielectric material capable of being subject to electrical breakdown, extends over a first part of the insulating layer that covers the first part of the substrate. The lower surface of this continuous dielectric layer is locally in contact with the respective metal interconnects of the memory cells. The dielectric region associated with a memory cell is then formed from the region of this dielectric layer situated locally in contact with the corresponding metal interconnect.

The continuous dielectric layer can be planar and can lie on the first part of the insulating layer.

According to another variant of the invention, in which the memory device comprises a matrix of memory cells, a discontinuous dielectric layer, formed from the dielectric material capable of being subject to electrical breakdown, is provided. The various portions of the discontinuous dielectric layer respectively extend over the bipolar transistors of the various cells and respectively incorporate the dielectric regions of the cells.

More precisely, and according to one embodiment of this variant, each memory cell comprises a capacitor extending over a first part of the insulating layer covering the first part of the substrate. This capacitor has a lower electrode in contact with the metal interconnect of the memory cell, an upper electrode and the corresponding portion of the discontinuous layer situated between the two electrodes. The dielectric region associated with the memory cell is then formed from the region of the portion of dielectric layer situated on top of the metal interconnect.

According to one embodiment of the invention, compatible with one or the other of the variants that have just been presented, the matrix of memory cells comprises first groups of cells all running in a first direction, for example parallel to the rows of the matrix, and second groups of cells all running in a second direction, for example parallel to the columns of the matrix. The memory device then comprises:

parallel semiconductor wells all running in the first direction and respectively associated with the first groups of cells, each well containing the control electrodes of the bipolar transistors of all the memory cells of the corresponding first group of cells

first metallizations in respective electrical contact with the wells, and

second metallizations all running in the second direction and respectively associated with the second groups of cells, each second metallization being in electrical contact with the second surfaces of the dielectric regions of the cells of the corresponding second group.

The cell programming means comprise the corresponding first metallization, the corresponding well and the corresponding second metallization.

According to one embodiment, compatible notably with the variant of the invention using a continuous dielectric layer, the first electrically conducting connection means of the cells of each first group comprise the corresponding first metallization and the corresponding well, while the second electrically conducting connection means of the cells of each second group comprise the corresponding second metallization.

According to one embodiment of the invention, in particular compatible with the variant using the discontinuous dielectric layer, the first electrically conducting connection means of the cells of each first group comprise the corresponding first metallization and the corresponding well, while the second electrically conducting connection means of the cells of each second group comprise the corresponding second metallization and the upper electrode of the corresponding capacitor.

The second metallizations advantageously form part of a metallization level of the integrated circuit, for example the first metallization level.

It will therefore be noted here that the invention is noteworthy, in particular, in the sense that it can be easily integrated into a conventional design of an integrated circuit.

By way of example, the first metallizations and the associated wells can form word lines of the matrix of memory cells, while the second metallizations can form bit lines.

Those skilled in the art will know how to adjust the breakdown voltage difference as a function of the technology used. By way of example, this breakdown voltage difference is greater than 3 volts, for example greater than or equal to 3.3 volts.

According to another aspect of the invention, a programming method is provided for a memory device such as was previously defined. According to this method, the breakdown voltage difference is applied between the second surface of the dielectric region and the control electrode of the transistor of the memory cell to be programmed so as to make the p-n junction of the transistor, formed between the first electrode and the control electrode, conduct.

By way of example, a breakdown voltage can be applied to the second surface of the dielectric region and ground potential to the control electrode of the transistor. Alternatively, the breakdown voltage could be applied to the control electrode of the transistor of the memory cell to be programmed and ground potential to the second surface of the dielectric region.

During the programming of a memory cell of the matrix, a de-programming voltage difference is applied for example between the second surface of the dielectric region and the control electrode of the transistor of each other memory cell, in other words of a memory cell that must not be programmed, which voltage difference is chosen so as to turn off the conduction of the upper p n junction of the bipolar transistor of this other memory cell.

The de-programming voltage difference is for example equal to zero volts or to the inverse of the breakdown voltage difference.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 is a partial schematic representation of one embodiment of a memory device according to the invention;

FIG. 2 is another partial schematic representation of the device in FIG. 1;

FIG. 3 is a partial schematic cross section along the line III-III in FIG. 2;

FIG. 4 illustrates schematically a programming operation of a memory cell of the device in FIG. 1;

FIG. 5 is another partial schematic representation of one embodiment of a memory device according to the invention;

FIG. 6 illustrates a variant embodiment of a memory device according to the invention; and

FIG. 7 illustrates another variant embodiment of a memory device according to the invention.

### DETAILED DESCRIPTION OF THE PREFERRED EMBODIMENTS

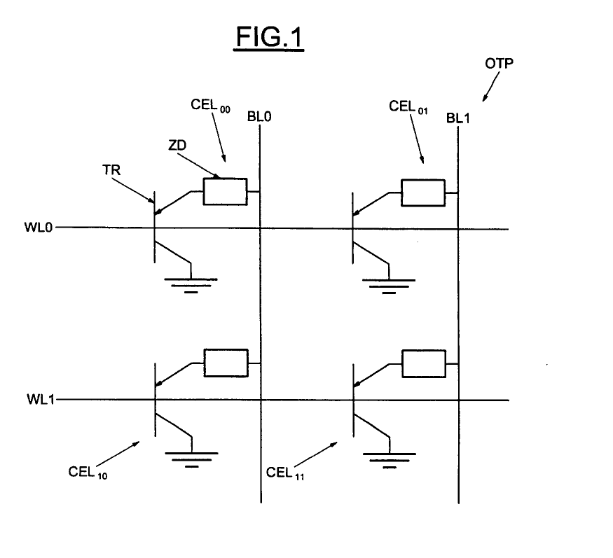

In FIG. 1, the reference OTP denotes a memory device of the irreversible electrical programming type or else of the one-time programmable type. In FIG. 1, for reasons of simplification, only the memory array itself of the OTP memory is shown, which here comprises, again for reasons of simplification, four memory cells organized in two rows WL0 and WL1 and two columns BL0 and BL1.

The rows WL0 and WL1 form word lines of the memory, whereas the columns BL0 and BL1 form bit lines of the memory.

Row and column decoders of conventional structure, which are known per se, are of course associated with this memory array.

Each cell CELᵢⱼ of the memory array comprises a fusible element ZD which is, as will be seen below, composed of a dielectric region and a bipolar transistor TR.

In the example described here, the bipolar transistor TR of each memory cell is a pnp transistor controlled on its control electrode (base) by the corresponding word line.

Furthermore, the fusible element ZD is connected between the corresponding bit line and the emitter of the transistor TR, whereas the collector of the transistor TR is, in this example, biased at ground potential.

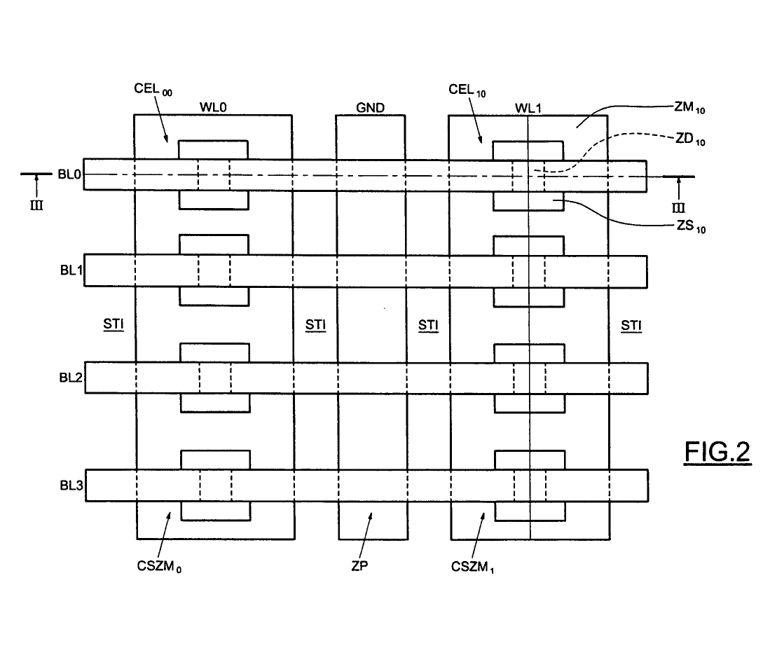

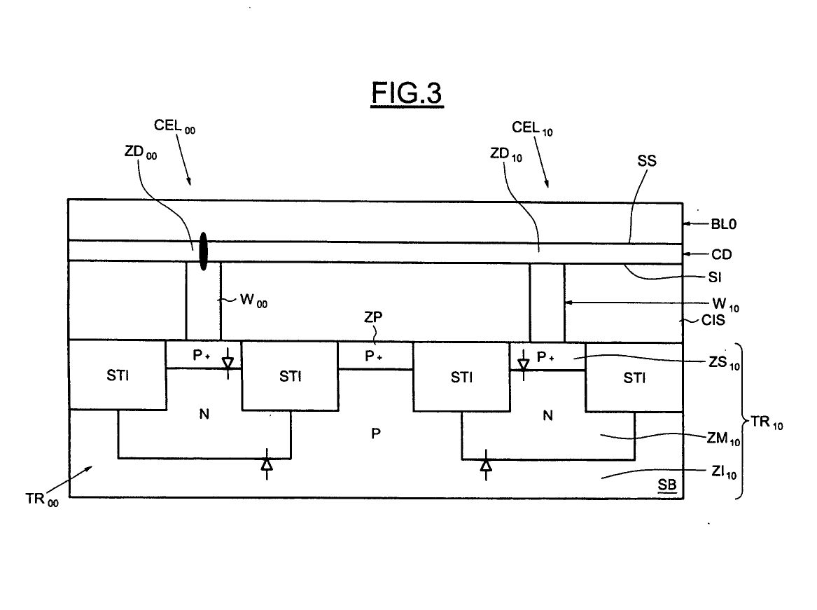

An exemplary embodiment of such a device is illustrated in FIGS. 2 and 3.

Each memory cell, for example the cell CEL₁₀, comprises a bipolar transistor TR₁₀ formed in a first part of a substrate SB, here of the p-conductivity type.

The bipolar transistor TR10 is consequently formed, in this example, from a multilayer of three semiconductor regions, namely an upper semiconductor region, a middle semiconductor region and a lower semiconductor region. The upper semiconductor region ZS₁₀, of the p-conductivity type, in this example is overdoped (P+) with respect to the lower semiconductor region ZI₁₀ of the multilayer, which is a part of the substrate SB. The middle semiconductor region ZM₁₀ is of the n-conductivity type.

The transistor TR₁₀ is here therefore a pnp bipolar transistor formed from an upper p-n junction between the upper region ZS and the middle region ZM and from a lower n-p junction between the middle region ZM and the lower region ZI.

The respective upper regions ZS of the various memory cells are isolated from one another by insulating regions STI which are here, by way of example, insulating regions of the “shallow trench” type.

The biasing of the substrate SB is provided by a metal contact (not shown here for reasons of simplification) coming into contact with an overdoped region P+ referenced ZP.

In fact, as can be seen in FIG. 2, all the middle regions ZM of all the cells CEL of the same word line form part of the same n-type well fabricated within the substrate SB.

Thus, as illustrated in FIG. 2, the well CSZM₀ contains all the middle regions ZM, which are in fact all the bases of the bipolar transistors of the memory cells of the word line WL0. Similarly, the well CSZM₁ contains all the middle regions of all the memory cells of the word line WL1.

These wells are biased by the contacts (of n+ type not shown in the figures) and the metallizations WLi.

Furthermore, as can also be seen in FIG. 2, the overdoped region ZP, which allows the substrate SB and consequently the lower semiconductor regions of the bipolar transistor multilayers to be biased, runs parallel to the well CSZMᵢ, and here the bias applied to the substrate SB is ground potential GND.

The part of the substrate SB in which the memory array OTP is fabricated is covered by an insulating layer CIS, for example a layer of silicon dioxide.

Metal interconnects, or contacts, Wᵢⱼ are fabricated in a conventional manner known per se through this insulating region CIS. They are for example formed from tungsten.

These metal interconnects Wᵢⱼ allow electrical connections to be formed between the respective upper semiconductor regions ZSᵢⱼ of the multilayers of the bipolar transistors of the memory cells and the lower surface SI of a continuous and plane dielectric layer CD which lies on the upper surface of the insulating layer CIS.

The metal tracks or metallizations BLⱼ are situated on the dielectric layer CD.

These metal tracks are fabricated in a conventional manner known per se within a metallization level of the integrated circuit, for example the first metallization level.

These metal tracks can for example be made of copper.

As illustrated in FIGS. 2 and 3, each memory cell CELᵢⱼ consequently comprises a dielectric region ZDᵢⱼ formed from the portion of dielectric layer situated between the corresponding metal interconnect Wᵢⱼ and the corresponding metal track BLⱼ.

The dielectric material forming the dielectric layer CD is a material capable of being subject to electrical breakdown, in other words of being irreversibly damaged so as to transform this dielectric region into a resistive region of low resistance.

As will be seen in more detail hereinbelow, this breakdown of a dielectric region is obtained by applying a breakdown voltage difference between the upper surface of the dielectric region and the middle semiconductor region of the multilayer of the bipolar transistor of the associated cell.

The phenomenon of breakdown of a dielectric disposed between two electrodes is well known to those skilled in the art. More precisely, when a high voltage is applied across the terminals of a capacitor formed from two electrodes separated by a dielectric oxide, defects are generated. When the density of defects reaches a critical value, a current will be established within the chain of defects and, by way of the heating effect, a conducting filament will be formed within the dielectric materials, thus changing this insulating material into a resistive one.

Several dielectric materials may be used for such an application. By way of non-limiting examples, silicon dioxide (SiO₂), phosphosilicate glass (PSG), silicon nitride (Si₃N₄), alumina (Al₂O₃) or borosilicate glass (BSG) will be mentioned. Such materials can be deposited as thin films, for example by a low-temperature process of the plasma-enhanced chemical vapor deposition (PECVD deposition) type.

The thickness of the dielectric material layer depends on the choice of material and on the breakdown voltage used. By way of example, for SiO₂ and for a breakdown voltage greater than or equal to 3.3 volts, a thickness of the order of 50 angstroms could be chosen.

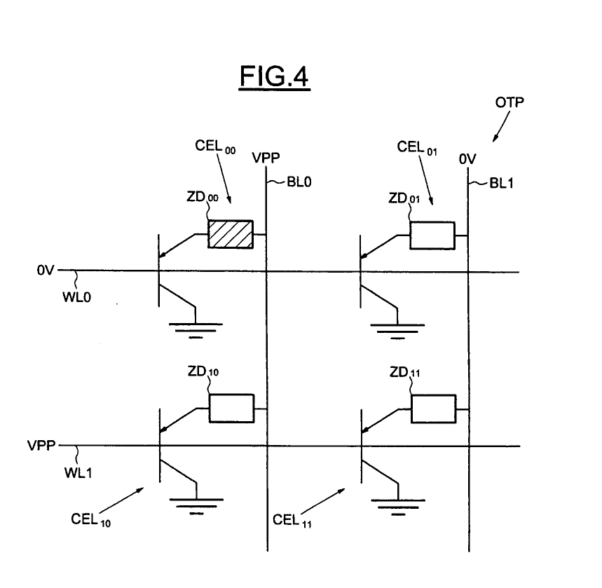

Now, reference will more particularly be made to FIG. 4 in order to illustrate the programming of the cell CEL₀₀, whereas the cells CEL₀₁, CEL₁₀ and CEL₁₁ are not programmed.

In order to effect this selective programming, the breakdown voltage VPP, which is much higher than the power supply voltage of the integrated circuit, is applied to the bit line BL0 and also to the word line WL1.

In addition, ground potential (0 volts) is applied to the word line WL0 and to the bit line BL1.

Ground potential is also applied to the substrate SB so as to bias the lower regions of the multilayers of the bipolar transistors of the memory cells at ground potential.

The application of these various voltages is effected by means of conventional design, such as for example voltage sources and logic selection means which have been represented schematically by the block BLC in FIG. 4, and which form part of the programming means.

As regards the cell CEL₀₀, the breakdown voltage VPP is therefore applied to the upper surface of the dielectric region ZD₀₀, while ground potential is applied to the middle region ZM₀₀ of the transistor TR₀₀.

The application of the breakdown voltage to the upper surface of the dielectric region ZD₀₀ leads to the creation of an electric field across this dielectric region, which has the effect of causing the potential of the metal interconnect W₀₀, and consequently of the region P+ of the transistor TR₀₀, to rise. When this potential exceeds the threshold voltage of the p-n diode of the transistor TR₀₀, formed between the region P+ and region N of this transistor, this diode becomes conducting since the n-type middle region ZM is at ground potential. Consequently, the potential of the lower surface of the dielectric region ZD₀₀ goes to ground. The breakdown voltage difference is then present across the terminals of the dielectric material, which causes its irreversible breakdown as illustrated in FIG. 3 by a vertical black line and by shading in FIG. 4.

In contrast, the dielectric regions ZD₀₁, ZD₁₁ and ZD₁₀ of the other memory cells are not subject to breakdown.

For example, with regard to the cell CEL₀₁, ground potential is applied to the bit line BL1 and to the word line WL0. Consequently, there is no voltage difference across the terminals of the dielectric material.

The same is true as regards the dielectric region ZD₁₀ of the cell CEL₁₀ since the same voltage VPP is applied to the upper surface of the dielectric region and to the corresponding well N.

As far as the cell CEL₁₁ is concerned, since ground potential is applied to the upper surface of the dielectric region ZD₁₁ and since the voltage VPP is applied to the corresponding well N, the upper p-n diode of the transistor TR₁₁ does not conduct. The dielectric material of the dielectric region ZD₁₁ does not therefore see a breakdown voltage difference across its terminals.

In order to read the contents of a memory cell, the bit lines are pre-charged up to the supply voltage Vdd, for example 1 volt, and instead of applying the voltage VPP to the bit line of the cell CEL₀₀, the read voltage Vdd is applied and the cell is selected by applying ground potential to the word line WL0. The value of the read current will of course depend on the dielectric insulating nature (dielectric not subject to breakdown) or conducting nature (dielectric subject to breakdown and becoming a resistance of low impedance).

It will therefore be noted that this aspect of the invention allows a cell to be programmed with a relatively low voltage and allows a very fast read operation to be obtained by reason of the bipolar behavior of the transistor (high read current).

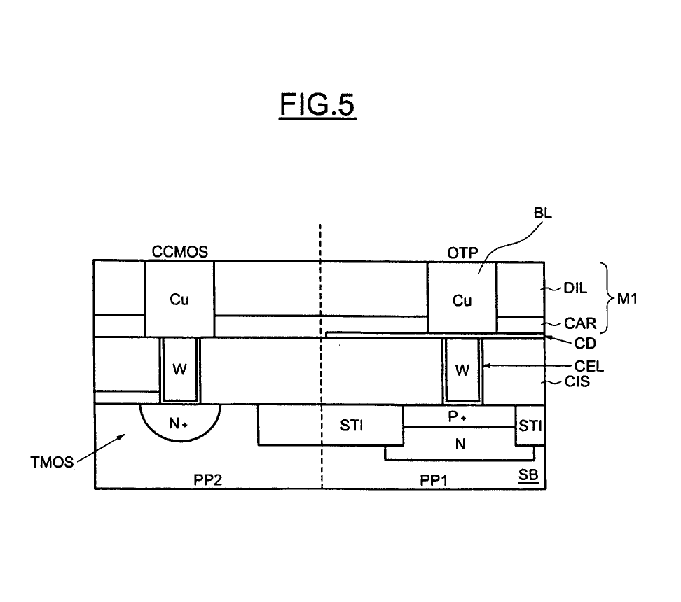

In FIG. 5, it can be seen than an OTP memory according to the invention can readily be an embedded memory, in other words fabricated in conjunction with the fabrication of other components, within the same substrate SB, and by using the same technological process.

More precisely, in FIG. 5, while the OTP memory array is formed within a first part PP1 of the substrate SB, a second part PP2 of the substrate SB here comprises a CMOS core referenced CCMOS, comprising for example several MOS transistors, a semiconductor region of which, for example the source region of a TMOS transistor, is shown in FIG. 5.

In actual fact, the fabrication of the OTP matrix only requires the production of one additional low-cost mask and one additional step for the deposition of the dielectric layer CD.

More precisely, following the fabrication of the CMOS core together with the bipolar transistors of the memory cells of the OTP memory array, and once the various metal interconnects W have been formed within the insulating layer CIS, the “CMOS core” part of the integrated circuit is masked, then the dielectric layer CD is deposited before depositing an etch stop layer CAR, for example a layer of silicon nitride, over the whole integrated circuit.

Subsequently, in a conventional manner known per se, the inter-level dielectric layer DIL is fabricated within which trenches are formed that are filled with material, for example with copper, so as to form the various bit lines BL.

Following the fabrication of this first metallization level M1, the other metallization levels of the integrated circuit are then be fabricated, as required, in a conventional manner.

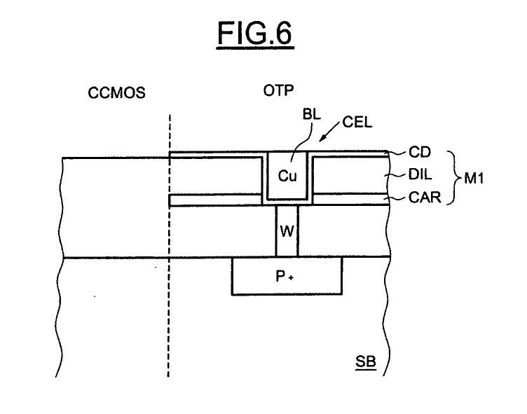

FIG. 6 illustrates another variant embodiment of the dielectric layer CD. In this variant, although the dielectric layer CD is continuous, it is not plane and does not wholly lie on the insulating layer CIS. It is simply deposited after fabrication of the trenches designed to receive the metal tracks of the metallization level M1 and before these tracks BL are filled with copper CU.

However, here again in this variant, it can be seen that a portion of dielectric material capable of being subject to electrical breakdown has been formed between the copper bit line BL and the underlying metal interconnect W made of tungsten.

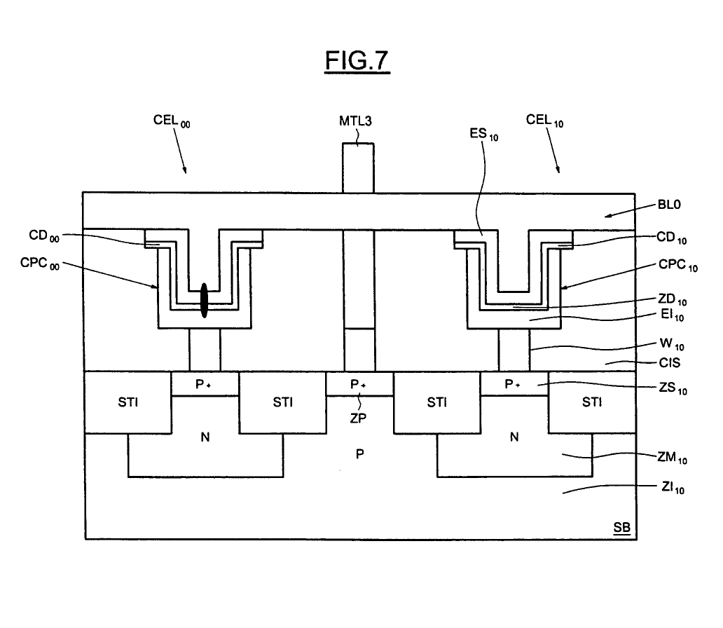

FIG. 7 illustrates another variant embodiment of an OTP memory array according to the invention, which this time is compatible with a fabrication process of the embedded DRAM type.

In this variant embodiment, the dielectric layer, formed from the dielectric material capable of being subject to electrical breakdown, is a discontinuous layer. More precisely, each memory cell, for example the cell CEL₁₀, comprises a capacitor CPC₁₀ extending over the insulating layer CIS. This capacitor CPC₁₀ has a lower electrode EI₁₀ in contact with the metal interconnect W₁₀ and an upper electrode ES₁₀. These electrodes can for example be made of titanium. The dielectric region ZD₁₀ is then formed from a region of the portion of the discontinuous dielectric layer CD₁₀ sandwiched between the two electrodes of the capacitor. The metallization BL0 has a part that fills the orifice of the capacitor situated above the upper electrode ES₁₀.

In this FIG. 7, the metallization MTL3 is also shown which allows the substrate SB to be biased via the overdoped region P+ referenced ZP.

The programming principle of such a memory array is identical to that described hereinabove. In this respect, in the left-hand part of FIG. 7, a cell CEL₀₀ has been shown whose dielectric material has been subject to irreversible breakdown.

The invention is not limited to the embodiments and implementation examples which have just been described and can also be applied notably in the case where the bipolar transistor of each memory cell is an npn transistor. In this case, in order to program the cell, ground potential (0 volts) is applied to the corresponding bit line and the breakdown voltage VPP is applied to the middle p-type semiconductor region of the transistor, which makes the upper p-n junction of the transistor conduct and allows the breakdown voltage difference to be applied across the terminals of the dielectric region of the cell.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. An integrated circuit, comprising:
a memory device, comprising at least one memory cell, formed within and on a first part of a semiconductor substrate, the memory cell comprising a bipolar transistor buried in the first part of the substrate, a dielectric region formed from a dielectric material capable of being subject to irreversible breakdown in the presence of a breakdown voltage difference applied thereto, this dielectric region being disposed on top of the substrate and having a first surface in electrical contact with a first electrode of the transistor, and a second surface opposite to the first, and
a programming circuit capable of applying the breakdown voltage difference between the second surface of the dielectric region and the control electrode of the transistor so as to make a p-n junction of the transistor, formed between the first electrode and the control electrode, conduct.

2. The integrated circuit according to claim 1, in which the dielectric region is situated on top of an insulating layer covering the first part of the substrate and the memory cell comprises a metal interconnect passing through the insulating layer between the first surface of the dielectric region and the first electrode of the bipolar transistor.

3. The integrated circuit according to claim 2, further comprising at least one active CMOS component formed within and on a second part of the same substrate also covered by the insulating layer.

4. The integrated circuit according to claim 2, wherein the bipolar transistor is formed from a multilayer of three semiconductor regions situated within the first part of the substrate, wherein the metal interconnect passes through the insulating layer between the first surface of the dielectric region and upper region of the multilayer, wherein the cell programming circuit comprises a first electrically conducting connection means in contact with the middle region of the multilayer and a second electrically conducting connection means in contact with the second surface of the dielectric region.

5. The integrated circuit according to claim 1, wherein the breakdown voltage difference is greater than 3 volts.

6. The integrated circuit according to claim 1 wherein the programming circuit operates to apply a breakdown voltage to the second surface of the dielectric region or to the control electrode of the transistor of the memory cell to be programmed while a ground potential is applied to the control electrode of the transistor or to the second surface of the dielectric region, respectively.

7. An integrated circuit, comprising:
a memory device, comprising a matrix of memory cells, each memory cell formed within and on a first part of a semiconductor substrate and comprising a bipolar transistor buried in the first part of the substrate, a dielectric region being disposed on top of the substrate and having a first surface in electrical contact with a first electrode of the transistor, and a second surface opposite to the first;
a continuous dielectric layer, formed from a dielectric material capable of being subject to irreversible breakdown in the presence of a breakdown voltage difference applied thereto, extending over the bipolar transistors of all the memory cells and incorporating the dielectric regions of the cells; and
a programming circuit capable of applying the breakdown voltage difference between the second surface of the dielectric region and the control electrode of the transistor so as to make a p-n junction of the transistor, formed between the first electrode and the control electrode, conduct.

8. The integrated circuit according to claim 7, wherein the dielectric region is situated on top of an insulating layer covering the first part of the substrate and each memory cell comprises a metal interconnect passing through the insulating layer between the first surface of the dielectric region and the first electrode of the bipolar transistor.

9. The integrated circuit according to claim 8, wherein the continuous dielectric layer extends over a first part of the insulating layer covering the first part of the substrate, the lower surface of this continuous dielectric layer being locally in contact with the respective metal interconnects of the memory cells, the dielectric region associated with a memory cell being formed from the region of this dielectric layer situated locally in contact with the corresponding metal interconnect.

10. The integrated circuit according to claim 9, wherein the dielectric layer is planar and lies on the first part of the insulating layer.

11. The integrated circuit according to claim 9, in which the matrix of memory cells comprises first groups of cells all running in a first direction and second groups of cells all running in a second direction, and in which the memory device comprises:
parallel semiconductor wells all running in the first direction and respectively associated with the first groups of cells, each well containing the control electrodes of the bipolar transistors of all the memory cells of the corresponding first group of cells,
first metallizations in respective electrical contact with the wells, and
second metallizations all running in the second direction and respectively associated with the second groups of cells, each second metallization being in electrical contact with the second surfaces of the dielectric regions of the cells of the corresponding second group,
the cell programming circuit comprising the corresponding first metallization, the corresponding well and the corresponding second metallization.

12. The integrated circuit according to claim 11, wherein the bipolar transistor is formed from a multilayer of three semiconductor regions situated within the first part of the substrate, wherein the metal interconnect passes through the insulating layer between the first surface of the dielectric region and upper region of the multilayer, wherein the cell programming circuit comprises a first electrically conducting connection means in contact with the middle region of the multilayer and a second electrically conducting connection means in contact with the second surface of the dielectric region, and wherein the first electrically conducting connection means of the cells of each first group comprise the corresponding first metallization and the corresponding well, and the second electrically conducting connection means of the cells of each second group comprise the corresponding second metallization.

13. The integrated circuit according to claim 12, wherein the second metallizations form part of a metallization level of the integrated circuit.

14. The integrated circuit according to claim 13, wherein the first metallizations and the associated wells form word lines of the matrix of memory cells and the second metallizations form bit lines.

15. The integrated circuit according to claim 7, wherein the breakdown voltage difference is greater than 3 volts.

16. The integrated circuit according to claim 7 wherein the programming circuit operates to apply a breakdown voltage to the second surface of the dielectric region or to the control electrode of the transistor of the memory cell to be programmed while a ground potential is applied to the control electrode of the transistor or to the second surface of the dielectric region, respectively.

17. The integrated circuit according to claim 7 wherein, during the programming of a memory cell of the matrix, the programming circuit operates to apply a de-programming voltage difference between the second surface of the dielectric region and the control electrode of the transistor of other memory cells, which voltage difference is chosen so as to turn off the conduction of an upper p-n junction of the bipolar transistor of the other memory cells.

18. The integrated circuit according to claim 17 wherein the de-programming voltage difference is equal to 0 volts or to the inverse of the breakdown voltage difference.

19. An integrated circuit, comprising:
a memory device, comprising a matrix of memory cells, each memory cell formed within and on a first part of a semiconductor substrate and comprising a bipolar transistor buried in the first part of the substrate, a dielectric region being disposed on top of the substrate and having a first surface in electrical contact with a first electrode of the transistor, and a second surface opposite to the first;
a discontinuous dielectric layer, formed from a dielectric material capable of being subject to irreversible breakdown in the presence of a breakdown voltage difference applied thereto, various portions of the discontinuous dielectric layer respectively extending over the bipolar transistors of the various cells and respectively incorporating the dielectric regions of the cells; and
a programming circuit capable of applying the breakdown voltage difference between the second surface of the dielectric region and the control electrode of the transistor so as to make a p-n junction of the transistor, formed between the first electrode and the control electrode, conduct.

20. The integrated circuit according to claim 19, wherein the dielectric region is situated on top of an insulating layer covering the first part of the substrate and each memory cell comprises a metal interconnect passing through the insulating layer between the first surface of the dielectric region and the first electrode of the bipolar transistor.

21. The integrated circuit according to claim 19, wherein each memory cell comprises a capacitor extending over a first part of the insulating layer covering the first part of the substrate and having a lower electrode in contact with the metal interconnect of the memory cell, an upper electrode and the corresponding portion of the discontinuous layer situated between the two electrodes, the dielectric region associated with the memory cell being formed from the region of the portion of dielectric layer situated on top of the metal interconnect.

22. The integrated circuit according to claim 21, wherein the dielectric layer is planar and lies on the first part of the insulating layer.

23. The integrated circuit according to claim 21, in which the matrix of memory cells comprises first groups of cells all running in a first direction and second groups of cells all running in a second direction, and in which the memory device comprises:
parallel semiconductor wells all running in the first direction and respectively associated with the first groups of cells, each well containing the control electrodes of the bipolar transistors of all the memory cells of the corresponding first group of cells,
first metallizations in respective electrical contact with the wells, and
second metallizations all running in the second direction and respectively associated with the second groups of cells, each second metallization being in electrical contact with the second surfaces of the dielectric regions of the cells of the corresponding second group,
the cell programming circuit comprising the corresponding first metallization, the corresponding well and the corresponding second metallization.

24. The integrated circuit according to claim 23, wherein the bipolar transistor is formed from a multilayer of three semiconductor regions situated within the first part of the substrate, wherein the metal interconnect passes through the insulating layer between the first surface of the dielectric region and upper region of the multilayer, wherein the cell programming circuit comprises a first electrically conducting connection means in contact with the middle region of the multilayer and a second electrically conducting connection means in contact with the second surface of the dielectric region, and wherein the first electrically conducting connection means of the cells of each first group comprise the corresponding first metallization and the corresponding well, and the second electrically conducting connection means of the cells of each second group comprise the corresponding second metallization and the upper electrodes of the corresponding capacitors.

25. The integrated circuit according to claim 24, wherein the second metallizations form part of a metallization level of the integrated circuit.

26. The integrated circuit according to claim 25, wherein the first metallizations and the associated wells form word lines of the matrix of memory cells and the second metallizations form bit lines.

27. The integrated circuit according to claim 19, wherein the breakdown voltage difference is greater than 3 volts.

28. The integrated circuit according to claim 19 wherein the programming circuit operates to apply a breakdown voltage to the second surface of the dielectric region or to the control electrode of the transistor of the memory cell to be programmed while a ground potential is applied to the control electrode of the transistor or to the second surface of the dielectric region, respectively.

29. The integrated circuit according to claim 19 wherein, during the programming of a memory cell of the matrix, the programming circuit operates to apply a de-programming voltage difference between the second surface of the dielectric region and the control electrode of the transistor of other memory cells, which voltage difference is chosen so as to turn off the conduction of an upper p-n junction of the bipolar transistor of the other memory cells.

30. The integrated circuit according to claim 29 wherein the de-programming voltage difference is equal to 0 volts or to the inverse of the breakdown voltage difference.
